(19) United States
(12) Patent Application Publication
(10) Pub. No.: US 2018/0299516 A1
(43) Pub. Date: Oct. 18, 2018

(54) METHOD FOR CALCULATING MAGNETIC FLUX LEAKAGE SIGNAL OF DEFECT

(71) Applicants: Hubei University of Technology, Wuhan (CN); Tsinghua University, Beijing (CN)

(72) Inventors: Songling HUANG, Beijing (CN); Xiaochun SONG, Wuhan (CN); Wei ZHAO, Beijing (CN); Lisha PENG, Beijing (CN); Jia YU, Beijing (CN)

(21) Appl. No.: 15/945,065

(22) Filed: Apr. 4, 2018

(30) Foreign Application Priority Data
Apr. 18, 2017 (CN) 201710252481.9

(51) Int. Cl. G01R 33/02

(52) U.S. Cl. CPC G01R 33/02

(57) ABSTRACT

The method for calculating an MFL signal of a defect includes: determining sizes l₀, w₀ and d₀ of an element defect according to sizes l, w and d of a target defect, acquiring an MFL signal H_{E} (x, y, z) of the element defect; subjecting the MFL signal H_{E}(x, y, z) to a three-dimensional Fourier transformation to acquire a frequency domain signal F_{E}(α, β, γ); subjecting the F_{E}(α, β, γ) to a translation transformation in the magnetization direction to acquire two frequency domain signals F_{Eα-}(α, β, γ) and F_{Eα+}(α, β, γ); combining the F_{Eα-}(α, β, γ) and F_{Eα+}(α, β, γ) to acquire a combined frequency domain signal F_{Ecombine}(α, β, γ); subjecting the combined frequency domain signal F_{Ecombine}(α, β, γ) to a three-dimensional inverse Fourier transformation to acquire an MFL signal H_{T}(x, y, z) of the target defect.

### CROSS-REFERENCE TO RELATED APPLICATION

This application claims priority to and benefits of Chinese Patent Application Serial No. 201710252481.9, filed with the State Intellectual Property Office of P. R. China on Apr. 18, 2017, the entire content of which is incorporated herein by reference.

### FIELD

The present disclosure relates to the field of non-destructive testing technology, and more particularly, to a method for calculating a magnetic flux leakage (MFL) signal of a defect.

### BACKGROUND

The MFL signal of defect is the basis for MFL detection and defect evaluation in ferromagnetic materials. As the relationship between the MFL signal and defect is not a one-to-one correspondence, the MFL signal cannot reflect the size of defect directly. The common solution is to establish a forward model for calculating the MFL signal of the given-size defect. Then, the parameters of the defect in the model are updated during the iteration so as to make the calculated MFL signal close enough to the target MFL signal, thus realizing the inversion of the size of defect. Therefore, calculating the MFL signal of defect efficiently, which is to establish the forward model, is essential for the MFL detection and defect evaluation.

In the related art, mostly the MFL signal of the target defect is directly calculated by a magnetic dipole method or a finite element method. However, in these methods, there is a lot of repetitive and redundant work in the iterative calculation of MFL signal, which greatly reduces the calculation efficiency of the MFL signal. In order to improve the calculation efficiency of the MFL signal of the target defect, it can be considered to use pre-calculated MFL signal of the given-size defect to represent the MFL signal of the target defect. It can greatly improve the calculation efficiency of the MFL signal of the target defect in principle. However, the relationship between the size of the target defect and the MFL signal is non-linear, and it is very difficult to use the pre-calculated MFL signal of the given-size defects to represent the MFL signal of the target defect directly. Currently, the method for calculating an MFL signal of a target defect based on the pre-calculated MFL signal of the given-size defect has not been realized in the related art.

### SUMMARY

Embodiments of the present disclosure seek to solve at least one of the problems existing in the related art to at least sonic extent.

For this, embodiments of a first aspect of the present disclosure provide a method for calculating an MIT signal of a defect, including:

determining sizes l₀, w₀ and d₀ of an element defect according to sizes l, w and d of a target defect, where l₀, w₀ and d₀ represent a length of the element defect in a magnetization direction, a width of the element detect in a direction vertical to the magnetization direction, a depth of the element defect in a thickness direction of a tested material, respectively, l, w and d represent a length of the target detect in the magnetization direction, a width of the target defect in the direction vertical to the magnetization direction, a depth of the target defect in the thickness direction of the tested material, respectively;

acquiring an MFL signal H_{E}(x, y, z) of the element defect;

subjecting the MFL signal H_{E}(x, y, z) of the element defect to a three-dimensional Fourier transformation to acquire a frequency domain signal F_{E}(α, β, γ);

subjecting the frequency domain signal F_{E}(α, β, γ) to a translation transformation in the magnetization direction to acquire two frequency domain signals F_{Eα-}(α, β, γ) and F_{Eα+} (α, β, γ);

combining the two frequency domain signals F_{Eα-}(α, β, γ) and F_{Eα+}(α, β, γ) to acquire a combined frequency domain signal F_{Ecombine}(α, β, γ); and

subjecting the combined frequency domain signal F_{Ecombine}(α, β, γ) to a three-dimensional inverse Fourier transformation to acquire an MFL signal H_{T}(x, y, z) of the target defect.

In an embodiment of the present disclosure, the target defect is a combination of element defects in the magnetization direction, and the sizes l₀, w₀ and d₀ of the element defect and the sizes w and d of the target defect meet the following conditions:

l₀=l/2, w₀=w, d₀=d.

In an embodiment of the present disclosure, the MFL signal H_{E}(x, y, z) of the element defect is acquired by a pre-set algorithm according to the sizes l₀, w₀ and d₀ of the element defect, in which the pre-set algorithm includes at least one of a magnetic dipole method, a finite element method or a neural network method.

In an embodiment of the present disclosure, subjecting the MFL signal H_{E}(x, y, z) of the element defect to a three-dimensional Fourier transformation to acquire a frequency domain signal F_{E}(α, β, γ) is performed according to a formula of

F_{E}(α, β, γ)=∫_{-∝}^{∝}∫_{-∝}^{∝}∫_{-∝}^{∝}H_{E}(x, y, z)·e^{-j(αx+βy+γz)}dxdydz,

where α, β, γ are spatial frequency variables in x, y, z directions, respectively,

In an embodiment of the present disclosure, subjecting the frequency domain signal F_{E}(α, β, γ) to a translation transformation in the magnetization direction to acquire two frequency domain signals F_{Eα-}(α, β, γ) and F_{Eα+}(α, β, γ) is performed according to formulas of

F_{Eα-}(α, β, γ)=F_{E}(α, β, γ)·e^{-jαl}^{₀}^{/2},

F_{Eα+}(α, β, γ)=F_{E}(α, β, γ)˜e^{jαl}^{₀}^{/2}.

In an embodiment of the present disclosure, combining the two frequency domain signals F_{Eα-}(α, β, γ) and F_{Eα+}(α, β, γ) to acquire a combined frequency domain signal F_{Ecombine} (α, β, γ) is performed according to a formula of

F_{Ecombine}(α, β, γ)=F_{Eα-}(α, β, γ)+F_{Eα+}(β, β, γ).

In an embodiment of the present disclosure, subjecting the combined frequency domain signal F_{Ecombine}(α, β, γ) to a three-dimensional inverse Fourier transformation to acquire an MFL signal H_{T}(x, y, z) of the target defect is performed according to a formula of

H_{T}(x, y, z)=∫_{-∝}^{∝}∫_{-∝}^{∝}∫_{-∝}^{∝}F_{Ecombine}(α, β, γ)·e^{j(αx+βy+γz)}dαdβdγ.

Embodiments of a second aspect of the present disclosure provide a device for calculating an MFL signal of a defect, including:

a processor; and

a memory for storing instructions executable by the processor;

in which the processor is configured to perform the method for calculating an MFL signal of a defect as described in embodiments of the first aspect of the present disclosure.

Embodiments of a third aspect of the present disclosure provide a non-transitory computer-readable storage medium having stored therein instructions that, when executed by a processor of a terminal, cause the terminal to perform the method for calculating an MFL signal of a defect as described in embodiments of the first aspect of the present disclosure.

Additional aspects and advantages of embodiments of the present disclosure will be given in part in the following descriptions, become apparent in part from the following descriptions, or be learned from the practice of the embodiments of the present disclosure.

### BRIEF DESCRIPTION OF THE DRAWINGS

The above and/or additional aspects and advantages of embodiments of the present disclosure will become apparent and more readily appreciated from the following descriptions made with reference to the drawings, in which:

FIG. 1 is a flow chart illustrating a method for calculating an MFL signal of a defect according to an embodiment of the present disclosure.

FIG. 2 is a diagram illustrating a comparison of results of MFL signals of a target defect with a size of 24 mm×12 mm×3.6 mm calculated by a method (i.e., an element combination method) according to an embodiment of the present disclosure and a finite element method.

FIG. 3 is a diagram illustrating a comparison of results of MFL signals of a target defect with a size of 48 mm×24 mm×4.8 mm calculated by a method (i.e., an element combination method) according to another embodiment of the present disclosure and a finite element method.

### DETAILED DESCRIPTION

Embodiments of the present disclosure will be described in detail and examples of embodiments are illustrated in the drawings. The same or similar elements and the elements having same or similar functions are denoted by like reference numerals throughout the descriptions. Embodiments described herein with reference to drawings are explanatory, serve to explain the present disclosure, and are not construed to limit embodiments of the present disclosure.

In the description of the present disclosure, it is to be illustrated that, terms such as “central”, “longitudinal”, “lateral”, “above”, “below”, “front”, “rear”, “left”, “right”, “vertical”, “horizontal”, “top”, “bottom”, “inner”, “outer”, as well as derivative thereof construed to refer to the orientation as then described or as shown in the drawings under discussion for simplifying the description of the present disclosure, but do not alone indicate or imply that the device or element referred to must have a particular orientation. Moreover, it is not required that the present disclosure is constructed or operated in a particular orientation and therefore are not construed to limit embodiments of the present disclosure. In addition, terms such as “first” and “second” are only used for description, which should not be understood as an indication of importance.

In the description of the present disclosure, it should be understood that, unless specified or limited otherwise, the terms “mounted,” “connected,” “coupled,” “fixed” and the like are used broadly, and may be, for example, fixed connections, detachable connections, or integral connections; may also be mechanical or electrical connections; may also be direct connections or indirect connections via intervening structures; may also be inner communications of two elements, which can be understood by those skilled in the art according to specific situations. Referring to the following descriptions and drawings, these and other aspects of the embodiments of the present disclosure will be apparent. In these descriptions and drawings, some specific approaches of the embodiments of the present disclosure are provided, so as to show some ways to perform the principle of the embodiments of the present disclosure, however it should be understood that the embodiment of the present disclosure is not limited thereby. Instead, the embodiments of the present disclosure include all the variants, modifications and their equivalents within the spirit and scope of the present disclosure as defined by the claims.

Embodiments of the present disclosure will be described with reference to drawings.

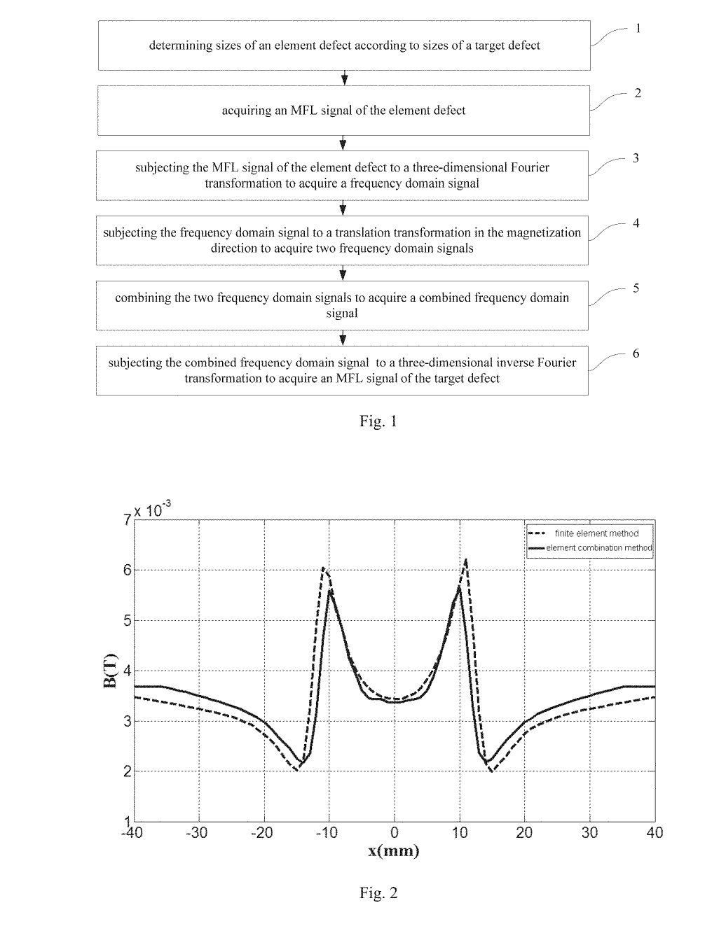

FIG. 1 is a flow chart illustrating a method for calculating an MFL signal of a defect according to an embodiment of the present disclosure. As shown in FIG. 1, the method includes the following operations illustrated at the following blocks.

At block 1, sizes l₀, w₀ and d₀ of an element defect are determined according to sizes l, w and d of a target detect.

Specifically, l₀, w₀ and d₀ represent a length of the element defect in a magnetization direction, a width of the element defect in a direction vertical to the magnetization direction, a depth of the element defect in a thickness direction of a tested material, respectively, l, w and d represent a length of the target defect in the magnetization direction, a width of the target defect in the direction vertical to the magnetization direction, a depth of the target defect in the thickness direction of the tested material, respectively.

In an embodiment of the present disclosure, the target defect is a combination of element defects in the magnetization direction, and the sizes l₀, w₀ and d₀ of the element defect and the sizes l, w and d of the target defect meet the following conditions:

l₀=l/2, w₀=w, d₀=d.

At block 2, an MFL signal H_{E}(x, y, z) of the element defect is acquired.

In an embodiment of the present disclosure, the MFL signal H_{E}(x, y, z) of the element defect is acquired by a pre-set algorithm according to sizes l₀, w₀ and d₀ of the element defect. Specifically, the pre-set algorithm includes at least one of a magnetic dipole method, a finite element method or a neural network method, that is, the pre-set algorithm includes, but are not limited to, these calculation methods given above as examples.

At block 3, the signal MFL signal (x, y, z) of the element defect is subjected to a three-dimensional Fourier transformation to acquire a frequency domain signal F_{E}(α, β, γ).

Specifically, at the block 3, the MFL signal (x, y, z) of the element defect is subjected to the three-dimensional Fourier transformation with a formula of

F_{E}(α, β, γ)=∫_{-∝}^{∝}∫_{-∝}^{∝}∫_{-∝}^{∝}H_{E}(x, y, z)·e^{-j(αx+βy+γz)}dxdydz,

where α, β, γ are spatial frequency variables in x, y, z directions, respectively,

At block 4, the frequency domain signal F_{E}(α, β, γ) is subjected to a translation transformation in the magnetization direction to acquire two frequency domain signals F_{Eα-}(α, β, γ) and F_{Eα+}(α, β, γ).

Specifically, at the block 4, the translation transformation is performed with formulas of

F_{Eα-}(α, β, γ)=F_{E}(α, β, γ)·e^{-jαl}^{₀}^{/2},

F_{Eα+}(α, β, γ)=F_{E}(α, β, γ)·e^{jαl}^{₀}^{/2}.

At block 5, the two frequency domain signals (α, β, γ) and F_{Eα+}(α, β, γ) are combined to acquire a combined frequency domain signal F_{Ecombine}(α, β, γ).

Specifically, at block 5, the two frequency domain signals F_{Eα-}(α, β, γ) and F_{Eα+}(α, β, γ) are combined according to a formula of

F_{Ecombine}(α, β, γ)=F_{Eα-}(α, β, γ)+F_{Eα+}(α, β, γ).

At block 6, the combined frequency domain signal F_{Ecombine}(α, β, γ) is subjected to a three-dimensional inverse Fourier transformation to acquire an MFL signal H_{T}(x, y, z) of the target defect.

Specifically, at block 6, the combined frequency domain signal (α, β, γ) is subjected to the three-dimensional inverse Fourier transformation with a formula of

H_{T}(z, y, z)=∫_{-∝}^{∝}∫_{-∝}^{∝}∫_{-∝}^{∝}F_{Ecombine}(α, β, γ)·e^{j(αx+βy+γz)}dαdβdγ.

As described above, with the method for calculating an MFL signal of a defect according to embodiments of the present disclosure, by operations like transformation, combination and inverse transformation for the pre-calculated MFL signals of the given-size defects, the MFL signal of the target defect, which is the combination of the given-size defects in the magnetization direction, may be acquired without repeating forward calculations according to such as finite element algorithm, thus improving calculation efficiency of the MFL signal of the defect. Therefore, the method has advantages of a simple model and a quick calculation.

In order to better describe the present disclosure, the method for calculating an MFL signal of a defect may be further discussed with reference to drawings and following specific embodiments.

### EMBODIMENT 1

In the present embodiment, the method for calculating an MFL signal of a defect include following operations.

Sizes of an element defect are determined according to sizes of a target defect. Specifically, the target defect has a length l of 24 mm in a magnetization direction, a width w of 12 mm in a direction vertical to the magnetization direction and a depth d of 3.6 mm in a thickness direction of a tested material. As the target defect is a combination of element defects in a magnetization direction, on this basis, the sizes of the element defect are selected as l₀=l/2=12 mm, w₀=w=12 mm and d₀=d=3.6 mm, where l₀, w₀ and d₀ represent a length of the element defect in the magnetization direction, a width of the element detect in the direction vertical to the magnetization direction, a depth of the element defect in the thickness direction of the tested material, respectively.

An MFL signal H_{E}(x, y, z) of the element defect is acquired. Specifically, the MFL signal H_{E} (x, y, z) of the element defect is acquired by pre-calculating with a finite element method according to the sizes of the element defect that l₀=12 mm, w₀=12 mm, d₀=3.6 mm.

The MFL signal H_{E}(x, y, z) of the element defect is subjected to a three-dimensional Fourier transformation to acquire a frequency domain signal F_{E}(α, β, γ). Specifically, the three-dimensional Fourier transformation is performed according to a formula of

F_{E}(α, β, γ)=∫_{-∝}^{∝}∫_{-∝}^{∝}∫_{-∝}^{∝}H_{E}(x, y, z)·e^{-j(αx+βy+γz)}dxdydz,

where α, β, γ are spatial frequency variables in x, y, z directions, respectively.

The frequency domain signal F_{E}(α, β, γ) is subjected to a translation transformation in the magnetization direction to acquire two frequency domain signals F_{Eα-}(α, β, γ) and F_{Eα+}(α, β, γ).

Specifically, the translation transformation is performed with formulas of

F_{Eα-}(α, β, γ)=F_{E}(α, β, γ)·e^{-jαl}^{₀}^{/2},

F_{Eα+}(α, β, γ)=F_{E}(α, β, γ)·e^{jαl}^{₀}^{/2}.

The two frequency domain signals F_{Eα-}(α, β, γ) and F_{Eα+}(α, β, γ) are combined to acquire a combined frequency domain signal F_{Ecombine}(α, β, γ). Specifically, the two frequency domain signals F_{Eα-}(α, β, γ) and F_{Eα+}(α, β, γ) are combined with a formula of

F_{Ecombine}(α, β, γ)=F_{Eα-}(α, β, γ)+F_{Eα+}(α, β, γ).

The combined frequency domain signal F_{Ecombine}(α, β, γ) is subjected to a three-dimensional inverse Fourier transformation to acquire an MFL signal H_{T}(x, y, z) of the target detect (24 mm×12 mm×3.6 mm).

Specifically, the combined frequency domain signal F_{Ecombine}(α, β, γ) is subjected to the three-dimensional inverse Fourier transformation with a formula of

H_{T}(x, y, z)=∫_{-∝}^{∝}∫_{-∝}^{∝}∫_{-∝}^{∝}F_{Ecombine}(α, β, γ)·e^{j(αx+βy+γz)}dαdβdγ.

Comparison between a curve of MFL signals of the target defect obtained by the above method and that obtained by the finite element method is shown in FIG. 2. It can be seen from FIG. 2 that, with the method in the present embodiment of the present disclosure, the target defect may be calculated by directly subjecting the MFL signal of the given-size element defect to the transformation and the combination without repeating the finite element calculation, such that calculation time is shortened significantly compared with that of the finite element method. Therefore, with the method according to embodiments of the present disclosure, the MFL signal of the target defect can be calculated in a simple model and a quick calculation.

### EMBODIMENT 2

In the present embodiment, the method for calculating an MFL signal of a defect include following operations.

Sizes of an element defect are determined according to sizes of a target defect. Specifically, the target defect has a length l of 48 mm in a magnetization direction, a width w of 24 mm in a direction vertical to the magnetization direction and a depth d of 4.8 mm in a thickness direction of a tested material. As the target defect is a combination of element defects in a magnetization direction, on this basis, the sizes of the element defect are selected as l₀=l/2=24 mm, w₀=w=24 mm and d₀=d=4.8 mm, where l₀, w₀ and d₀ represent a length of the element defect in the magnetization direction, a width of the element defect in the direction vertical to the magnetization direction, a depth of the element defect in the thickness direction of the tested material, respectively.

An MFL signal H_{E}(x, y, z) of the element detect is acquired. Specifically, the MFL signal H_{E} (x, y, z) of the element defect is acquired by pre-calculating with a finite element method according to the sizes of the element defect that l₀=24 mm, w₀=24 mm, d₀=4.8 mm.

The MFL signal H_{E}(x, y, z) of the element defect is subjected to a three-dimensional Fourier transformation to acquire a frequency domain signal F_{E}(α, β, γ). Specifically, the three-dimensional Fourier transformation is performed according to a formula of

F_{E}(α, β, γ)=∫_{-∝}^{∝}∫_{-∝}^{∝}∫_{-∝}^{∝}H_{E}(x, y, z)·e^{-j(αx+βy+γz)}dxdydz,

where α, β, γ are spatial frequency variables in x, y, z directions, respectively.

The frequency domain signal F_{E}(α, β, γ) is subjected to a translation transformation in the magnetization direction to acquire two frequency domain signals F_{Eα-}(α, β, γ)) and F_{Eα+}(α, β, γ). Specifically, the translation transformation is performed with formulas of

F_{Eα-}(α, β, γ)=F_{E}(α, β, γ)·e^{-jαl}^{₀}^{/2},

F_{Eα+}(α, β, γ)=F_{E}(α, β, γ)·e^{jαl}^{₀}^{/2}

The two frequency domain signals F_{Eα-}(α, β, γ) and F_{Eα+}(α, β, γ) are combined to acquire a combined frequency domain signal F_{Ecombine}(α, β, γ). Specifically, the two frequency domain signals F_{Eα-}(α, β, γ) and F_{Eα+}(α, β, γ) are combined with a formula of

F_{Ecombine}(α, β, γ)=F_{Eα-}(α, β, γ)+F_{Eα+}(α, β, γ).

The combined frequency domain signal F_{Ecombine}(α, β, γ) is subjected to a three-dimensional inverse Fourier transformation to acquire an MFL signal H_{T}(x, y, z) of the target defect (48 mm×24 mm×4.8 mm).

Specifically, the combined frequency domain signal F_{Ecombine}(α, β, γ) is subjected to the three-dimensional inverse Fourier transformation with a formula of

H_{T}(x, y, z)=∫₋₄^{∝}∫_{-∝}^{∝}∫_{-∝}^{∝}F_{Ecombine}(α, β, γ)·e^{j(αx+βy+γz)}dαdβdγ.

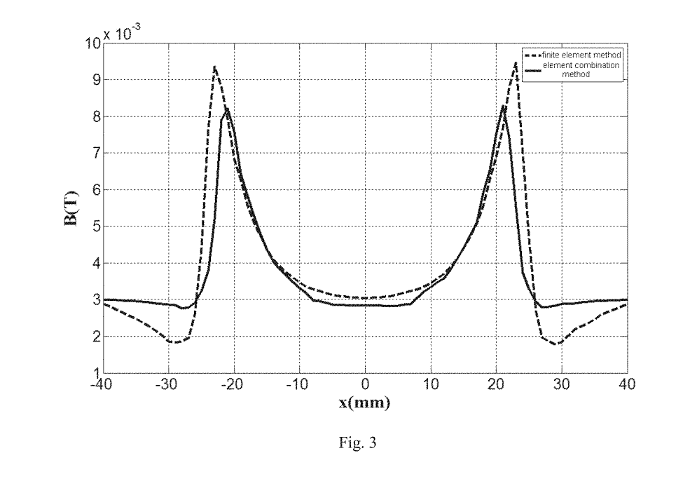

Comparison between a curve of MFL signals of the target defect obtained by the above method and that obtained by the finite element method is shown in FIG. 3. It can be seen from FIG. 3 that, with the method in the present embodiment of the present disclosure, the target defect may be calculated by directly subjecting the MFL signal of the known element defect to the transformation and the combination, without repeating the finite element calculation, such that calculation time is shortened significantly compared with that of the finite element method. Therefore, with the method according to embodiments of the present disclosure, the MFL signal of the target defect can be calculated in a simple model and a quick calculation. According to an embodiment of the present disclosure, a device for calculating an MFL signal of a defect is provided. The device includes a processor, and a memory for storing instructions executable by the processor, in which the processor is configured to perform the method for calculating an MFL signal of a defect according to the abovementioned embodiments of the present disclosure.

According to an embodiment of the present disclosure, a non-transitory computer-readable storage medium is provided having stored therein instructions that, when executed by a processor of a terminal, causes the terminal to perform a method for calculating an MFL signal of a defect according to the abovementioned embodiments of the present disclosure.

It will be understood that, the flow chart or any process or method described herein in other manners may represent a module, segment, or portion of code that includes one or more executable instructions to implement the specified logic function(s) or that includes one or more executable instructions of the steps of the progress. Although the flow chart shows a specific order of execution, it is understood that the order of execution may differ from that which is depicted. For example, the order of execution of two or more boxes may be scrambled relative to the order shown. Also, two or more boxes shown in succession in the flow chart may be executed concurrently or with partial concurrence. In addition, any number of counters, state variables, warning semaphores, or messages might be added to the logical flow described herein, for purposes of enhanced utility, accounting, performance measurement, or providing troubleshooting aids, etc. It is understood that all such variations are within the scope of the present disclosure. Also, the flow chart is relatively self-explanatory and is understood by those skilled in the art to the extent that software and/or hardware can be created by one with ordinary skill in the art to carry out the various logical functions as described herein.

The logic and step described in the flow chart or in other manners, for example, a scheduling list of an executable instruction to implement the specified logic function(s), it can be embodied in any computer-readable medium for use by or in connection with an instruction execution system such as, for example, a processor in a computer system or other system. In this sense, the logic may include, for example, statements including instructions and declarations that can be fetched from the computer-readable medium and executed by the instruction execution system. In the context of the present disclosure, a “computer-readable medium” can be any medium that can contain, store, or maintain the printer registrar for use by or in connection with the instruction execution system. The computer readable medium can include any one of many physical media such as, for example, electronic, magnetic, optical, electromagnetic, infrared, or semiconductor media. More specific examples of a suitable computer-readable medium would include, but are not limited to, magnetic tapes, magnetic floppy diskettes, magnetic hard drives, or compact discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

Although the device, system, and method of the present disclosure is embodied in software or code executed by general purpose hardware as discussed above, as an alternative the device, system, and method may also be embodied in dedicated hardware or a combination of software/general purpose hardware and dedicated hardware. If embodied in dedicated hardware, the device or system can be implemented as a circuit or state machine that employs any one of or a combination of a number of technologies. These technologies may include, but are not limited to, discrete logic circuits having logic gates for implementing various logic functions upon an application of one or more data signals, application specific integrated circuits having appropriate logic gates, programmable gate arrays (PGA), field programmable gate arrays (FPGA), or other components, etc. Such technologies are generally well known by those skilled in the art and, consequently, are not described in detail herein.

It can be understood that all or part of the steps in the method of the above embodiments can be implemented by instructing related hardware via programs, the program may be stored in a computer readable storage medium, and the program includes one step or combinations of the steps of the method when the program is executed.

In addition, each functional unit in the present disclosure may be integrated in one progressing module, or each functional unit exists as an independent unit, or two or more functional units may be integrated in one module. The integrated module can be embodied in hardware, or software. If the integrated module is embodied in software and sold or used as an independent product, it can be stored in the computer readable storage medium, to The computer readable storage medium may be, but is not limited to, read-only memories, magnetic disks, or optical disks.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

What is claimed is:

1. A method for calculating a magnetic flux leakage (MFL) signal of a defect, comprising:
determining sizes l₀, w₀ and d₀ of an element defect according to sizes l, w and d of a target defect, where l₀, w₀ and d₀ represent a length of the element defect in a magnetization direction, a width of the element defect in a direction vertical to the magnetization direction, a depth of the element defect in a thickness direction of a tested material, respectively, l, w and d represent a length of the target detect in the magnetization direction, a width of the target defect in the direction vertical to the magnetization direction, a depth of the target defect in the thickness direction of the tested material, respectively;
acquiring an MFL signal H_{E}(x, y, z) of the element defect;
subjecting the MFL signal H_{E}(x, y, z) of the element defect to a three-dimensional Fourier transformation to acquire a frequency domain signal F_{E}(α, β, γ);
subjecting the frequency domain signal F_{E}(α, β, γ) to a translation transformation in the magnetization direction to acquire two frequency domain signals F_{Eα-}(α, β, γ) and F_{Eα+}(α, β, γ);
combining the two frequency domain signals F_{Eα-}(α, β, γ) and F_{Eα+}(α, β, γ) to acquire a combined frequency domain signal F_{Ecombine}(α, β, γ); and
subjecting the combined frequency domain signal F_{Ecombine}(α, β, γ) to a three-dimensional inverse Fourier transformation to acquire an MFL signal H_{T}(x, y, z) of the target defect.

2. The method according to claim 1, wherein the target defect is a combination of element defects in the magnetization direction, and the sizes l₀, w₀ and d of the element defect and the sizes l, w and d of the target defect meet the following conditions:
l₀=l/2, w₀=w, d₀=d.

3. The method according to claim 1, wherein the MFL signal H_{E}(x, y, z) of the element defect is acquired by a pre-set algorithm according to the sizes l₀, w₀ and d₀ of the element defect, wherein the pre-set algorithm comprises at least one of a magnetic dipole method, a finite element method and a neural network method.

4. The method according to claim 1, wherein subjecting the MFL signal H_{E}(x, y, z) of the element defect to a three-dimensional Fourier transformation to acquire a frequency domain signal F_{E}(α, β, γ) is performed according to a formula of
F_{E}(α, β, γ)=∫_{-∝}^{∝}∫_{-∝}^{∝}∫_{-∝}^{∝}H_{E}(x, y, z)·e^{-j(αx+βy+γz)}dxdydz,
where α, β, γ are spatial frequency variables in x, y, z directions, respectively.

5. The method according to claim 1, wherein subjecting the frequency domain signal F_{E}(α, β, γ) to a translation transformation in the magnetization direction to acquire two frequency domain signals F_{Eα-}(α, β, γ) and F_{Eα+}(α, β, γ) is performed according to formulas of
F_{Eα-}(α, β, γ)=F_{E}(α, β, γ)·e^{-jαl}^{₀}^{/2},
F_{Eα+}(α, β, γ)=F_{E}(α, β, γ)·e^{jαl}^{₀}^{/2}.

6. The method according to claim 1, wherein combining the two frequency domain signals F_{Eα-}(α, β, γ) and F_{Eα+}(α, β, γ) to acquire a combined frequency domain signal F_{Ecombine}(α, β, γ) is performed according to a formula of
F_{combine}(α, β, γ)=F_{Eα-}(α, β, γ)+F_{Eα+}(α, β, γ).

7. The method according to claim 1, wherein subjecting the combined frequency domain signal F_{Ecombine}(α, β, γ) to a three-dimensional inverse Fourier transformation to acquire an MFL signal H_{T}(x, y, z) of the target defect is performed according to a formula of
H_{T}(x, y, z)=∫_{-∝}^{∝}∫_{-∝}^{∝}∫_{-∝}^{∝}F_{Ecombine}(α, β, γ)·e^{j(αx+βy+γz)}dαdβdγ.

8. A device for calculating an MFL signal of a defect, comprising:
a processor; and
a memory for storing instructions executable by the processor;
wherein the processor is configured to perform a method for calculating MEL signal of a defect, the method comprising:
determining sizes l₀, w₀ and d₀ of an element defect according to sizes l, w and d of a target defect, where l₀, w₀ and d₀ represent a length of the element defect in a magnetization direction, a width of the element defect in a direction vertical to the magnetization direction, a depth of the element defect in a thickness direction of a tested material, respectively, l, w and d represent a length of the target defect in the magnetization direction, a width of the target defect in the direction vertical to the magnetization direction, a depth of the target defect in the thickness direction of the tested material, respectively;
acquiring an MFL signal H_{E}(x, y, z) of the element defect;
subjecting the MFL signal H_{E}(x, y, z) of the element defect to a three-dimensional Fourier transformation to acquire a frequency domain signal F_{E}(α, β, γ);
subjecting the frequency domain signal F_{E}(α, β, γ) to a translation transformation in the magnetization direction to acquire two frequency domain signals F_{Eα-}(α, β, γ) and F_{Eα+}(α, β, γ);
combining the two frequency domain signals F_{Eα-}(α, β, γ) and F_{Eα+}(α, βγ) to acquire a combined frequency domain signal F_{Ecombine}(α, β, γ); and
subjecting the combined frequency domain signal F_{Ecombine}(α, βγ) to a three-dimensional inverse Fourier transformation to acquire an MFL signal H_{T}(x, y, z) of the target defect.

9. The device according to claim 8, wherein the target defect is a combination of element defects in the magnetization direction, and the sizes l₀, w₀ and d₀ of the element defect and the sizes l, w and d of the target defect meet the following conditions:
l₀=l/2, w₀=w, d₀=d.

10. The device according to claim 8, wherein the MFL signal H_{E}(x, y, z) of the element defect is acquired by a pre-set algorithm according to the sizes l₀, w₀ and d₀ of the element defect, wherein the pre-set algorithm comprises at least one of a magnetic dipole method, a finite element method and a neural network method.

11. The device according to claim 8, wherein subjecting the MFL signal H_{E}(x, y, z) of the element defect to a three-dimensional Fourier transformation to acquire a frequency domain signal F_{E}(α, β, γ) is performed according to a formula of
F_{E}(α, β, γ)=∫_{-∝}^{∝}∫_{-∝}^{∝}∫_{-∝}^{∝}H_{E}(x, y, z)·e^{-j(αx+βy+γz)}dxdydz,
where α, β, γ are spatial frequency variables in x, y, z directions, respectively.

12. The device according to claim 8, wherein subjecting the frequency domain signal F_{E}(α, β, γ) to a translation transformation in the magnetization direction to acquire two frequency domain signals F_{Eα-}(α, β, γ) and F_{Eα+}(α, β, γ) is performed according to formulas of
F_{Eα-}(β, β, γ)=F_{E}(α, β, γ)˜e^{-jαl}^{₀}^{/2},
F_{Eα+}(α, β, γ)=F_{E}(α, β, γ)·e^{jαl}^{₀}^{/2},

13. The device according to claim 8, wherein combining the two frequency domain signals F_{Eα-}(α, β, γ) and F_{Eα+}(α, β, γ) to acquire a combined frequency domain signal F_{Ecombine}(α, β, γ) is performed according to a formula of
F_{Ecombine}(α, β, γ)=F_{Eα-}(α, β, γ)+F_{Eα+}(α, β, γ).

14. The device according to claim 8, wherein subjecting the combined frequency domain signal F_{Ecombine}(α, β, γ) to a three-dimensional inverse Fourier transformation to acquire an MFL signal H_{T}(x, y, z) of the target detect is performed according to a formula of
H_{T}(x, y, z)=∫_{-∝}^{∝}∫_{-∝}^{∝}∫_{-∝}^{∝}F_{Ecombine}(α, β, γ)·e^{j(αx+βy+γz)}dαdβdγ.

15. A non-transitory computer-readable storage medium having stored therein instructions that, when executed by a processor of a terminal, cause the terminal to perform a method for calculating an MFL signal of a defect, the method comprising:
determining sizes l₀, w₀ and d₀ of an element defect according to sizes l, w and d of a target defect, where l₀, w₀ and d₀ represent a length of the element defect in a magnetization direction, a width of the element detect in a direction vertical to the magnetization direction, a depth of the element defect in a thickness direction of a tested material, respectively, l, w and d represent a length of the target defect in the magnetization direction, a width of the target defect in the direction vertical to the magnetization direction, a depth of the target defect in the thickness direction of the tested material, respectively;
acquiring an MFL signal H_{E}(x, y, z) of the element defect;
subjecting the MFL signal H_{E}(x, y, z) of the element defect o a three-dimensional Fourier transformation to acquire a frequency domain signal F_{E}(α, β, γ);
subjecting the frequency domain signal F_{E}(α, β, γ) to a translation transformation in the magnetization direction to acquire two frequency domain signals F_{Eα-}(α, β, γ) and F_{Eα+}(α, β, γ);
combining the two frequency domain signals F_{Eα-}(α, β, γ) and F_{Eα+}(α, β, γ) to acquire a combined frequency domain signal F_{Ecombine}(α, βγ); and
subjecting the combined frequency domain signal F_{Ecombine}(α, β, γ) to a three-dimensional inverse Fourier transformation to acquire an MFL signal H_{T}(x, y, z) of the target detect
